(19) United States
(12) Patent Application Publication
(10) Pub. No.: US 2024/0147876 A1
(43) Pub. Date: May 2, 2024

(54) THINNED PHASE CHANGE MATERIAL IN BRIDGE CELL MEMORY AS A WEIGHT FOR ARTIFICIAL INTELLIGENCE APPLICATION

(71) Applicant: International Business Machines Corporation, Armonk, NY (US)

(72) Inventors: Kangguo Cheng, Schenectady, NY (US); Michael Rizzolo, Delmar, NY (US)

(21) Appl. No.: 17/978,560

(22) Filed: Nov. 1, 2022

(51) Int. Cl. H01L 45/00

(52) U.S. Cl. CPC H01L 45/1253; H01L 45/1226; H01L 45/1675

(57) ABSTRACT

A memory cell structure includes a substrate having formed thereon a first electrode and second electrodes physically spaced apart. A phase change material (PCM) cell is formed on the substrate and forms a bridge extending between the first and second electrodes, the phase change material including a first end electrically contacting the first electrode and a second end contacting the second electrode. The phase change material cell includes a thinned surface portion where a surface topography of the phase change material cell is decreased relative to a surface topography of the phase change material cell surface at the first and second ends. The PCM thickness is intentionally gradually tapered to localize the formation of the phase change region. During PCM programming, corresponding to the weight update in machine learning, the phase change of the PCM occurs at the thinnest surface portion and gradually propagates towards the electrodes.

### BACKGROUND

The present disclosure relates in general to semiconductor devices and methods of manufacturing semiconductor devices and, in particular, to phase change memory devices with a bridge cell.

Phase change materials can change phase between an amorphous state and a crystalline state by application of specific levels of electrical current or voltage. The amorphous state can be characterized by a relatively higher electrical resistivity than the crystalline state, causing different levels of voltages or current being used for setting the phase of the phase change material. A phase change memory element can use phase change material to increase memory capacity. In an aspect, the different voltage or current levels being applied to change phase among an off state (e.g., no voltage or current applied), the amorphous state, the crystalline state, and different types of the crystalline state, can cause the phase change memory to represent more than two values (e.g., binary) of data that can be stored in a phase change memory element.

Phase change memory (PCM) has emerged as a viable option for machine learning. For example, it can be used to represent weights of a neural network for artificial intelligence (AI) applications.

In AI application, it is highly desired to have the conductance of the PCM changing gradually, i.e., in an analog way

### SUMMARY

In one embodiment, there is provided a PCM memory device structure with a bridge cell architecture.

System and methods described herein are directed to forming a phase change memory (PCM) device with a PCM bridge cell architecture having a thinned GST portion. In an embodiment, the PCM device includes two electrodes and the thickness of the PCM material, e.g., germanium-antimony-tellurium (GST), varies gradually from the electrodes towards the center of the bridge. The thinnest GST portion is at the center of the GST bridge.

During PCM programming, corresponding to the weight update in machine learning, the phase change of GST occurs at the thinnest portion of the bridge and gradually propagates towards the electrodes. Such a gradual phase change allows gradual change of GST in both SET and RESET operations, which is highly desired for AI applications

In an embodiment, a semiconductor structure is generally described. The semiconductor structure comprises: a substrate having formed thereon a first electrode and second electrodes physically spaced apart; a phase change material cell directly on the substrate extending between the first and second electrodes, the phase change material including a first end electrically contacting the first electrode and a second end contacting the second electrode; and the phase change material cell having a thinned surface portion wherein a surface topography of the phase change material cell at the thinned surface portion is decreased relative to a surface topography of the phase change material cell surface at each the first and second ends.

In a further embodiment, there is provided a method for forming a phase change memory element. The method can include forming a first electrode and second electrode physically spaced apart on a substrate; depositing a phase change material layer directly on the substrate between and the first electrode and second electrode, the phase change material including a first end electrically contacting the first electrode and a second end contacting the second electrode; and forming a thinned surface portion of the phase change material layer between the first and second electrodes, wherein a surface topography of the phase change material cell at the thinned surface portion is decreased relative to a surface topography of the phase change material cell surface at each the first and second ends.

In a further embodiment, there is provided a method of programming a phase change material (PCM) memory device. The method comprises: initializing a resistive state of a PCM memory device, the PCM memory device comprising: a substrate having formed thereon a first electrode and second electrodes physically spaced apart; a phase change material cell directly on the substrate extending between the first and second electrodes, the phase change material including a first end electrically contacting the first electrode and a second end contacting the second electrode; and the phase change material cell having a thinned surface portion wherein a surface topography of the phase change material cell at the thinned surface portion is decreased relative to a surface topography of the phase change material cell surface at each the first and second ends; and applying an electronic pulse signal to the first or second electrode to cause a resistive state change of the phase change material cell at a location corresponding to the thinned surface portion.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1A depicts a top-down view of a bridge PCM cell region including PCM memory devices to be formed in accordance with an present embodiment;

FIG. 1B depicts a cross-sectional view taken along a line X-X of one PCM memory device of FIG. 1A to be formed;

FIG. 2A depicts a top-down view of a resulting structure and FIG. 2B depicts a cross-sectional view taken along line X-X of FIG. 2A of the resulting structure after patterning the dielectric cap layer to form a trench between each of two respective electrodes for forming the bridge cell;

FIG. 3A depicts a top-down view of a resulting structure after performing the additional step of filling the formed trenches with a phase change material bridge 45 and after tailoring the thickness of GST to vary gradually from the electrodes towards the center of the bridge and FIG. 3B depicts a cross-sectional view taken along line X-X of FIG. 3A of the resulting structure;

FIGS. 4A-4D depict a further embodiment of a method that employs ion beam etching (IBE) processes to achieve GST bridge thinning according to embodiments herein;

FIG. 5 shows a top-down wafer view depicting a rotational preference depicted by arrows that ensures the electrode masks the GST bridge;

FIGS. 6A-6D depict top-down views of a further embodiment of a PCM bridge memory device area on the wafer as a result of processes employing ion beam etching (IBE) to achieve GST bridge thinning of PCM bridge devices in three dimensions according to an embodiment herein.

FIG. 7A depicts a cross-sectional view of the structure of FIG. 6B taken along line X-X. the structure formed on a substrate and including two electrodes and the GST bridge formed between and electrically connecting each electrode;

FIG. 7B shows a cross-sectional view of the PCM cell structure of FIG. 7A subject to an ion Beam etching performed at low tilt angles to thin the GST in the center of the bridge in an embodiment;

FIG. 8 is a cross sectional view of a structure formed after removing a hard mask layer and patterning a spacer of the exemplary structure of FIG. 7 in one embodiment; and

FIG. 9 illustrates an example of a resistive memory crossbar array 500 that can implement a matrix multiplication operation of a machine learning algorithm according to an embodiment.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following descriptions, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

As used herein, a “phase change memory cell” means a structure including at least one phase change material that is interposed between two contacts, where at least a portion of the phase change material can be switched from an amorphous state into a crystalline state, and vise-versa, by application of energy, wherein the crystalline state has a lower resistivity than the amorphous state.

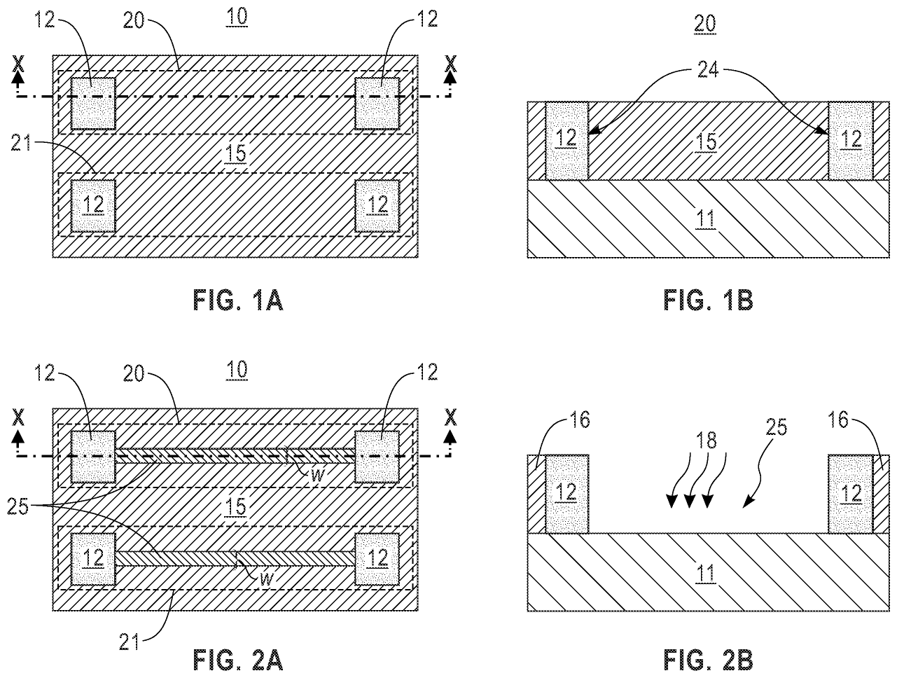

FIG. 1A depicts a top-down view of a bridge PCM cell region 10 including PCM memory devices 20, 21 to be formed in accordance with the present embodiment. FIG. 1B depicts a cross-sectional view taken along a line X-X of one PCM memory device 20 to be formed.

As shown in FIG. 1A, there is depicted an initial structure of a bridge PCM cell device 20 including two electrodes 12 physically spaced apart in the X-direction by a gap and embedded in a dielectric material layer 15 such as SiN deposited on a surface of a substrate. Electrodes 12 are electrically conducting and typically composed of at least one electrically conducting metal or metal containing material, e.g., metal oxide or metal nitride.

As shown in the cross-sectional view depicted in FIG. 1B, there is first provided a substrate 11, e.g., a Si material substrate or on any other common dielectric in semiconductor processing including, but not limited to: SiOx, SiNx, SiCxNy, SiCOH. The substrate 11 can already include other devices (not shown) such as transistors, isolation structures, contacts (electrodes), or other conductive structures (e.g., landing pads, wires). The thickness of substrate layer 11 can range from between 5 nm to 5 μm or thicker (in the Z-direction).

The cross-sectional view depicted in FIG. 1B shows a resulting structure after a further step of depositing a dielectric material layer 15 above the substrate 11. This dielectric material layer 15 can be a dielectric material cap layer of a low dielectric coefficient (low-k dielectric), e.g., a metal nitride layer 15 such as SiN, SiCN, SiCNH, multilayers of SiCN/SiO, etc. Dielectric material layer 15 can have a thickness (in the Z-direction) of about 5 nm to about 500 nm. Of course, thicker and thinner layers are also suitable.

As shown in FIG. 1B depicting the cross-sectional view taken along line X-X of the bridge PCM cell region 20 of FIG. 1A, there is depicted the further step of forming two electrodes 12 defining the PCM bridge memory cell device 20. In an illustrative and non-limiting embodiment, the electrodes 12 are spaced apart on the SiN substrate layer at a distance such as 1 μm or less.

The electrodes 12 of the bridge PCM cell of FIG. 1B can be formed from the initial structure of FIG. 1B where using an electrode patterning process and performing subsequent lithographic mask patterning and etching processes of the dielectric cap layer 15 results in the forming of vertical electrode openings or trenches 24 in the dielectric cap layer 15. These formed vertical openings or trenches 24 may additionally expose a top surface of a landing pad or other underlying conductor structure or device (not shown) at a PCM memory cell region. In an embodiment, a dry etching process, such as an anisotropic etching process, for example, a reactive-ion etching (RIE) or any types of plasma etching, can be used, or a wet etching process can be used to form the vertical electrode openings 24. These vertical openings for forming each electrode 12 may be formed to a depth ranging from between 5 nm and 500 nm.

Then, to form each electrode 12, a metal-containing material, e.g., electrically conducting metal, metal oxide or metal nitride material including, but not limited to: copper, silver, gold tungsten, titanium, tantalum, aluminum, nickel, chromium, oxides thereof, nitrides thereof, and combinations and alloys thereof, is deposited into the formed electrode openings 24 in the dielectric cap layer 15 by a material deposition process. The formed metal electrodes 12 can be formed by any suitable deposition process or any suitable combination of multiple processes, including but not limited to: electroplating, electroless plating, atomic layer deposition (ALD), chemical vapor deposition (CVD), physical vapor deposition (PVD), etc.

FIG. 2A depicts a top-down view of a resulting structure and FIG. 2B depicts a cross-sectional view taken along line X-X of FIG. 2A of the resulting structure after patterning the dielectric cap layer to form a trench between each of two respective electrodes 12 for forming the bridge cell.

In the top-down view of FIG. 2A, there is shown a resulting structure after patterning the SiN to form a trench 25 for the bridge cell devices 20, 21. That is, using further lithographic mask patterning and etching processes 18, the dielectric cap layer material between the formed electrodes 12 is removed to form an elongated trench 25 for the bridge PCM cell. The etching can include a dry etching process, such as an anisotropic etching process, for example, a reactive-ion etching (RIE) or any types of plasma etching that can be used to remove the dielectric cap material layer. As shown in the cross-sectional view of FIG. 2B, taken along line X-X of FIG. 2A, side portions 16 of the original dielectric cap layer 15 structure in the PCM memory cell region 20 remain abutting an outer sidewall surface of each electrode 12.

In an embodiment, as shown in the top-down view of FIG. 2A, the formed trench 25 for the bridge of the PCM cell device runs the length of the space or gap, e.g., about 1 μm, between the electrodes and the trench 25 is thinner in width w than the thickness of the electrodes. In a non-limiting embodiment, the line width of each trench 25 ranges from between 10 nm and 500 nm.

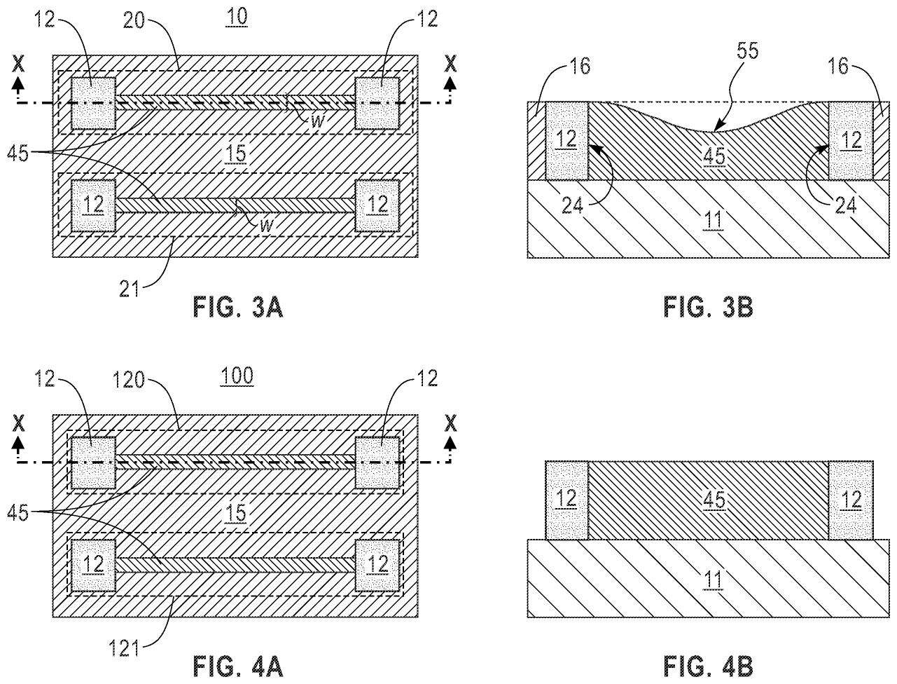

FIG. 3A depicts a top-down view of a resulting structure after performing the additional step of filling the formed trenches with a phase change material bridge 45 and after tailoring the thickness of GST to vary gradually from the electrodes towards the center of the bridge and FIG. 3B depicts a cross-sectional view taken along line X-X of FIG. 3A of the resulting structure.

Bridge 45 is formed from a chalcogenide material, one that has a phase transition from amorphous to crystalline upon application of an external force, such as an applied current or voltage. Suitable phase change materials include, but are not limited to, binary and ternary compounds of germanium antimony tellurium Ge, Sb and Te (GST), and any other materials that possess hysteretic phase change characteristics. The compounds involving Ge, Sb and Te are often referred to as GST compounds or materials. Besides GST, other suitable PCM materials can include but are not limited to: silicon-antimony-tellurium (Si—Sb—Te) alloys, gallium-antimony-tellurium (Ga—Sb—Te) alloys, germanium-bismuth-tellurium (Ge—Bi—Te) alloys, indium-tellurium (In—Se) alloys, arsenic-antimony-tellurium (As—Sb—Te) alloys, silver-indium-antimony-tellurium (Ag—In—Sb—Te) alloys, germanium-indium-antimony-tellurium (Ge—In—Sb—Te) alloys, germanium-antimony (Ge—Sb) alloys, antinomy-tellurium (Sb—Te) alloys, silicon-antinomy (Si—Sb) alloys, and combinations thereof. In some embodiments, the phase change material can further include nitrogen, carbon, and/or oxygen.

One specific example of a suitable material for bridge 45 is Ge₂Sb₂Te₅. In its standard phase, a chalcogenide material is in its amorphous state, having a high electrical resistivity. Upon the application of heat, for example by passing a current therethrough, the chalcogenide material transitions to its crystalline state, having a low electrical resistivity. The chalcogenide material can be reverted back to its amorphous state by melting, e.g., by the application of a higher heat.

More specifically, in the top-down view of FIG. 3A, there is shown a resulting structure after depositing the GST phase change memory material in the formed trenches 25 to form the electrically conducting GST bridge 45 of the bridge cell devices 20, 21. Each formed GST bridge electrically connects two spaced apart metal electrodes 12. That is, using further lithographic mask patterning and material deposition processes, the GST material is deposited into the formed trenches 25 to form each GST bridge 45 for respective cells 20, 21.

The phase change material bridge 45 extends between electrodes 12. The length of bridge 45 (in the X-direction) is usually 1 μm or less, and in some embodiments can be less than 100 nm, e.g., about 20-75 nm. The width of bridge 45 (in the Y-direction) is usually about 10 nm to about 500 nm, and in embodiments, is less than the width of electrodes 12. In these embodiments, bridge 45 is typically centered on electrodes 12. Bridge 45 is selectively electrically conducting, providing electrical connection between electrodes 12 on demand.

After depositing the GST phase change memory material into each trench 25, the formed GST bridge 45 is then subject to a chemical-mechanical planarization or polishing (CMP) process. In particular, the CMP process is controlled to intentionally achieve a dishing of a local surface topography due to overpolishing at a localized area. For instance, controlling a dwell time of CMP polishing steps at a particular area or region can accomplish a local dishing or topographic surface variation at that region. In an embodiment, this “overpolish” CMP process is performed to intentionally result in a thinning of a surface topography at a middle portion or region of the GST bridge. Further, as a result of application of CMP overpolishing, the PCM cell thickness is gradually tapered to localize the formation of the phase change region. That is, the applied CMP process to the GST bridge 45 results in a topography that includes a surface gradually thinning of the GST bridge 45 at or near the middle 55 of the bridge 45. In particular, since each trench 45 is very long (e.g., ≤1 μm), CMP “dishing” causes more GST removal in the middle of the trench, resulting in thinnest GST in the middle of the GST.

FIG. 3B depicts a cross-sectional view taken along line X-X of FIG. 3A of the resulting structure after performing the additional CMP step that resulting in CMP “dishing” that causes more GST removal in the middle 55 of the bridge, resulting in thinnest GST in the middle of the GST bridge of formed PCM memory devices 20, 21. In an embodiment, the thinning includes a locally topographical depression 55 or decrease in height by ≥10% of the original height of the GST trench layer 45.

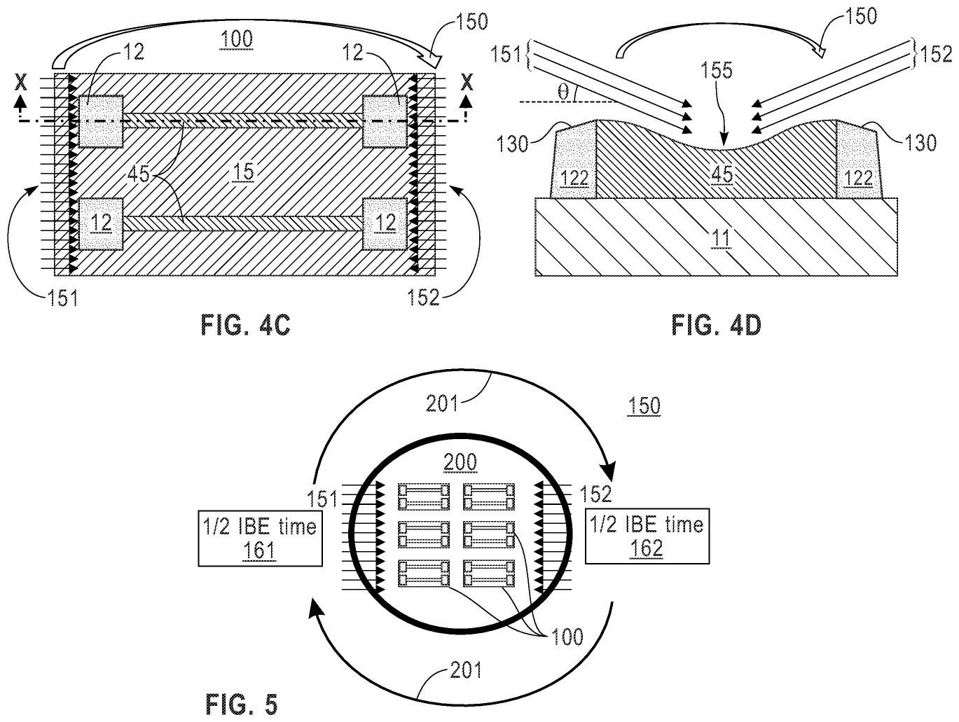

FIGS. 4A-4D depict a further embodiment of a method that employs ion beam etching (IBE) processes to achieve GST bridge thinning.

As shown in the top-down view of FIG. 4A, there is shown a resulting intermediate PCM memory cell structure after depositing the GST phase change memory material in a trench 25 formed between two spaced apart metal electrodes 12 in a dielectric material layer 15, e.g., SiN, formed above a substrate as in FIG. 3A. FIG. 4A particularly depicts a PCM memory region 100 including formed GST PCM memory devices 120, 121, each device including two electrodes 12 and a thinned PCM material (e.g., GST) bridge 45 of the bridge cell devices 120, 121. That is, using further lithographic mask patterning and material deposition processes, the GST material is deposited into the formed trenches 25 to form each GST bridge 45 for respective cells 120, 121. In an embodiment, a conventional masked subtractive etch process can be used including steps such as: blanket depositing GST material, patterning a hard mask (HM), an etching process, e.g., RIE GST, and then a strip.

FIG. 4B depicts a cross-sectional view of the structure of FIG. 4A taken along line X-X. As shown the resulting PCM memory device is formed on a substrate 11 and includes two electrodes 12 and the GST bridge formed between and electrically connecting each electrode 12.

As an alternative to the embodiment of FIGS. 3A-3B, as shown in FIG. 4C, after depositing the GST phase change memory material into each trench to form PCM memory device (GST) bridges 45, the formed GST bridge 45 is then subject to an IBE processing 150 to reduce the thickness of the bridge 45. In the embodiment shown in FIG. 4C, and in the corresponding cross-sectional view of FIG. 4D taken along line X-X of FIG. 4C, an ion Beam etching streams 151, 152 are performed at low tilt angles to thin the GST in the center of the bridge 45. That is, in FIGS. 4C, 4D, an IBE stream 151 is carried out at a low tilt angle “θ” relative to the horizontal that is directed from the left side toward the center region 155 of the PCM memory cell bridge 45 and further IBE processing stream 152 is carried out at a low tilt angle θ relative to the horizontal that is directed from right side toward the center region of the PCM memory cell bridge 45 to result in a locally confined thinning of the PCM bridge middle region 155. In an embodiment, the thinning includes a locally topographical depression 55 or decrease in height by ≥10% of the original height of the GST trench layer 45. In an embodiment, the IBE performed at low tilt angles can dwell at preferential rotation angles to enhance electrode shadowing when the electrode is physically blocking the impinging ion beam, so the region behind the electrode is considered shadowed. The range of rotation angles is from 50-85 degrees (0 deg=perpendicular to wafer surface, 90 deg=parallel to wafer surface). In an embodiment, the IBE etching can further result in a corresponding topographical angling of the surface 130 of each electrode 122 corresponding to the applied angle of the etching ion beams 151, 152. For example, IBE beams 152 originating from the right side can result in a downward angling of the topographic surface 130 of the left electrode 122 and IBE beams 151 originating from the left side can result in a downward angling of the topographic surface 130 of the right memory cell electrode 122. It is understood that the IBE tilt angle can be adjusted to compensate for electrode pitch. Further, the IBE system (not shown) can configure IBE for very tight controls over remaining GST thicknesses (e.g., can uniformly thin to 1's or 10's of nm due to beam uniformity/non selectivity).

As shown in FIG. 5, in an embodiment, the IBE processes 150 employing etch beams 151, 152 shown in FIGS. 4C, 4D can successively performed. That is, one-half of the total applied IBE process time can be applied to the wafer 200 containing one or more formed PCM bridge cell memory regions 100 while the wafer is in a first position, and then the wafer can be rotated as depicted by arrows 201 to a second position where for the remaining one-half IBE process time can be applied while the wafer 200 containing one or more formed PCM bridge cell memory regions 100 is in the second position. In an embodiment, a rotational speed of the wafer 200 can be programmed to ensure that the electrode masks the GST material such that the thickness of the middle 155 of the GST bridge can be reduced. FIG. 5 particularly shows a top-down wafer view depicting a rotational preference depicted by arrows 201 that ensures the electrode masks the GST bridge. In an embodiment, the masking locally blocks the ion beam from etching the PCM material close to the electrode, with gradually increasing the amount of removal as the etching moves further from the electrode. Further, as shown in FIG. 5, an IBE application dwell time of approximately one-half the total IBE time is employed, i.e., for each one-half wafer rotation. That is, in a first ½ wafer rotation 201, one-half the total IBE processes time 161 is employed directing ion etch beams 151 towards the wafer 200 at the low tilt angle θ, while in the next ½ wafer rotation 201, a second one-half the total IBE processes time 162 is employed to direct ion etch beams 152 towards the wafer 200 at the low tilt angle θ.

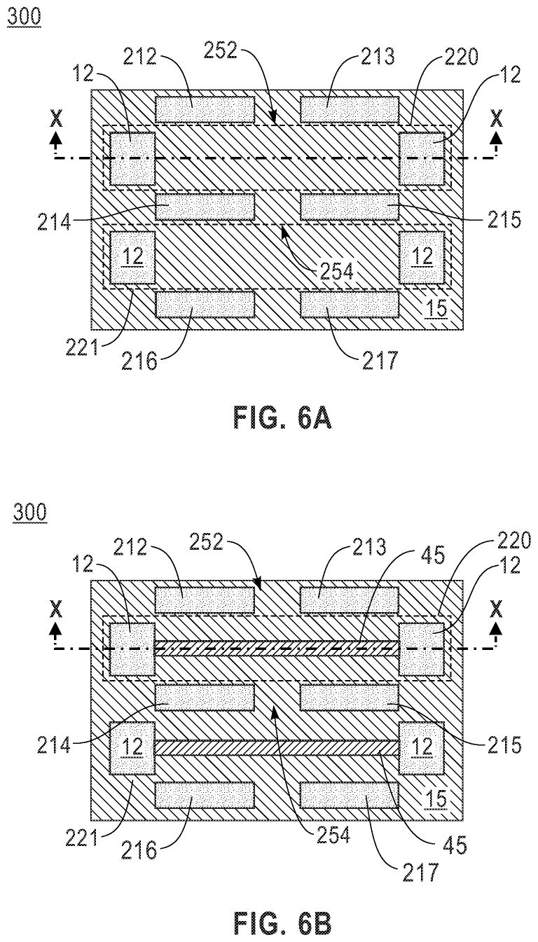

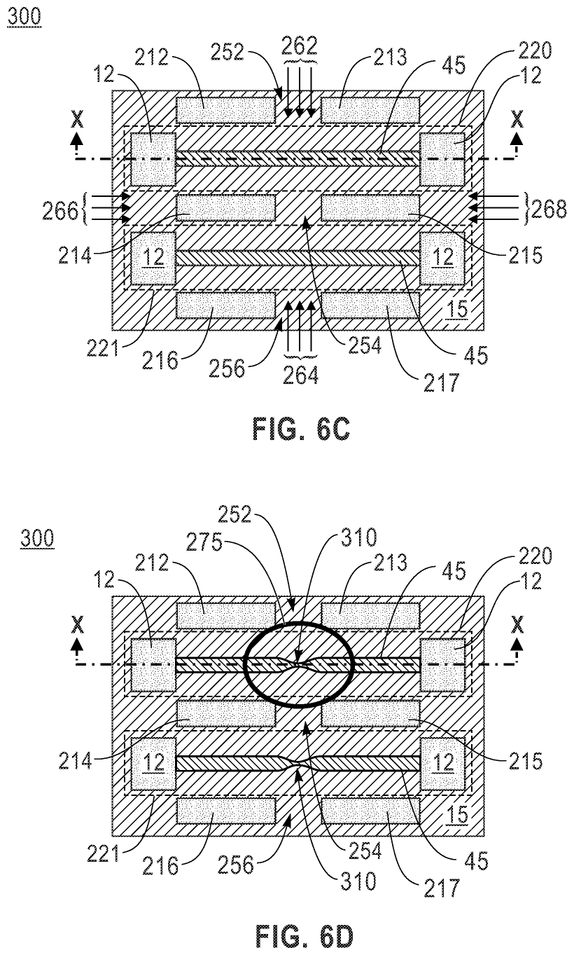

FIGS. 6A-6D depict top-down views of a further embodiment of a PCM bridge memory device area 300 on the wafer as a result of processes employing ion beam etching (IBE) to achieve GST bridge thinning of PCM bridge devices in three dimensions according to an embodiment herein. In the embodiment of FIG. 6A, there is first shown a resulting structure after depositing a dielectric material layer 15, e.g., a metal nitride layer 15 such as SiN, SiCN, SiCNH, multilayers of SiCN/SiO, etc. above a substrate (not shown) and after the further step of forming two metal electrodes 12 (e.g., of Ta, Ti, Cu, Ru, etc and conductive nitrides) defining the PCM bridge memory cell device 220 as in FIG. 1A. In an illustrative and non-limiting embodiment, the electrodes 12 are spaced apart on the SiN substrate layer at a distance such as 1 μm. Additionally formed in this embodiment are a configuration of metal-containing rectangular shaped dummy electrodes 212-215 that function to aid in patterning select region of the GST bridge to be formed. In the top-down views of FIG. 6A-6D, two rectangular shaped dummy electrodes 212, 213 are each oriented horizontally and have edges aligned along a length of and on one side of the PCM bridge portion of the memory cell device 220 to be built. In this embodiment, the two dummy electrodes 212, 213 are spaced apart to leave an opening or gap 252 in between edges of the aligned dummy electrodes through which ion etch beams can be directed. This opening corresponds to a middle of the GST bridge of PCM bridge cell 220 to be formed. Similarly, two other rectangular shaped dummy electrodes 214, 215 are formed with each oriented and aligned horizontally along the length of and on the opposite side of the PCM memory cell device 220 to be built. In this embodiment, the two dummy electrodes 214, 215 are spaced apart to leave an opening or gap 254 in between edges of the aligned dummy electrodes to which ion etch beams can be directed. A similar configuration of dummy electrodes 216, 217 and corresponding gap therebetween are formed around the additional PCM bridge memory cell device 221 to be formed. In embodiments, ion beams (or like particle beams) are applied at preferred tilt/rotational angles to achieve a tailored etching of the GST bridge structure. Using dummy electrodes 212-217 allow the IBE to locally etch in the X-axis direction Y-axis direction as well as the Z-axis direction.

The electrodes 12 and dummy electrodes 212-217 of FIG. 6A can be formed using an electrode patterning process and performing lithographic mask patterning and etching processes through the dielectric cap layer 15 that results in the forming of corresponding vertical electrode and dummy electrode openings (not shown) in the dielectric cap layer 15. In an embodiment, a dry etching process, such as an anisotropic etching process, for example, a RIE or any types of plasma etching, can be used, or a wet etching process can be used to form the vertical electrode and dummy electrode openings.

Then, to form each electrode 12 and dummy electrodes 212-217, a metal material, e.g., metal material including but not limited to: Ta, Ti, Cu, Ru, etc and conductive nitrides, is deposited into the formed electrode and dummy electrode openings in the dielectric cap layer 15 by a CVD, ALD, or PVD material deposition process.

As shown in the top-down view of FIG. 6B, there is shown a resulting intermediate PCM memory cell structure after further etching of a trench between electrodes 12 and after depositing the GST phase change memory material in the formed trench to form the GST phase change memory bridge 45. That is, using further lithographic mask patterning and material deposition processes, the GST material is deposited into each formed trench to form the GST bridge 45 that is electrically connected to the two spaced apart metal electrodes 12 in the dielectric material layer 15, e.g., SiN, formed above a substrate.

FIG. 6C depicts an IBE process employed to tailor the thinning of the GST bridge 45 formed between the two electrodes 12 of each formed GST PCM memory device 220, 221 in PCM memory cell region 300; each respective device including respective two electrodes 12 and a thinned PCM material (e.g., GST) bridge 45 of the bridge cell devices 220, 221. As shown in FIG. 6C, highly-directional particle streams (e.g., ions) 262, 264, 266, 268 are directed at the dielectric layer including the electrodes and GST bridge from all directions in a vacuum chamber to allow for a locally confined thinning of the GST bridge 45 in all three (3) dimensions near the middle of the GST bridge. As shown, due to the presence of dummy electrodes 213-217, highly-directional beams can be directed in between the openings present between the edges of the aligned dummy electrodes. For example, in an embodiment, highly-directional etch beams 262 are concentrated between the opening 252 situated in between edges of the aligned dummy electrodes 212, 213. Likewise, highly-directional etch beams 264 are concentrated between the opening 256 situated in between edges of the aligned dummy electrodes 216, 217. Further, highly-directional etch beams 266 are concentrated between the opening situated in between edges of two electrodes 12 on one side of each cell 220, 221 and similarly, highly-directional etch beams 268 are concentrated between the opening situated in between edges of two opposing electrodes 12 on one side of each cell 220, 221.

As shown in the top-down view of FIG. 6D, the concentration of these directed IBE particle streams 262, 264, 266, 268 utilizing the dummy electrodes results in the localized thinning 310 of the GST bridge 45 in three dimensions and locally confined near a middle portion 275 of the bridge in an alignment with the openings 252, 254, 256 of the dummy electrodes. That is, in an embodiment, besides achieving the local topographic surface variation along the X-axis at or near the middle portion of the GST bridge 45, the localized thinning 310 includes a thinning of the GST bridge width in the Y-axis direction at that localized middle portion. As in the other embodiments, the phase change material thickness of bridge 45 is locally decreased in three dimensions by an amount greater than or equal to (≥) 10% between electrodes to cause preferential heating locally.

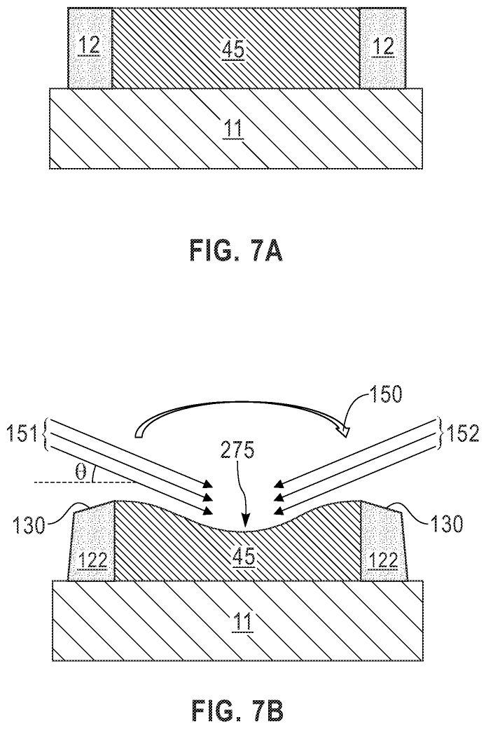

FIG. 7A depicts a cross-sectional view of the structure of FIG. 6B taken along line X-X. As shown the resulting PCM memory device is formed on a substrate 11 and includes two electrodes 12 and the GST bridge formed between and electrically connecting each electrode 12.

FIG. 7B shows a cross-sectional view of the PCM cell structure of FIG. 7A subject to an ion beam etching 151, 152 is performed at low tilt angles to shape the surface topography including thinning the GST in the center region of the bridge 45. That is, in FIG. 7B, an IBE particle stream 151 is carried out at a low tilt angle “θ” relative to the horizontal that is directed from the left side toward the center region 275 of the PCM memory cell bridge 45 and a further IBE particle stream 152 is carried out at a low tilt angle θ relative to the horizontal that is directed from right side toward the center region 275 of the PCM memory cell bridge 45 to result in a locally confined thinning of the PCM bridge middle region 275. To achieve thinning, the ions can be any common ones like Ar, N, Xe, or gas clusters. Accelerating voltages can range from between 100-5000 V. In an embodiment, the thinning includes a locally topographical depression or decrease in height by ≥10% of the original height of the GST trench layer 45. In an embodiment, the IBE at low tilt angles can dwell at preferential rotation angles to enhance electrode shadowing. In an embodiment, the IBE etching can further result in a corresponding topographical angling of the surface 130 of each electrode 122 corresponding to the applied angle of the etching ion beams 151, 152. For example, IBE streams 152 originating from the right side can result in a downward angling of the topographic surface 130 of the left electrode 122 and IBE streams 151 originating from the left side can result in a downward angling of the topographic surface 130 of the right memory cell electrode 122. It is understood that the IBE tilt angle can be adjusted to compensate for electrode pitch. Further, the IBE system (not shown) can configure IBE streams for very tight controls over remaining GST thicknesses (e.g., can uniformly thin to 1's or 10's of nm due to beam uniformity/non selectivity).

That is, in an embodiment, an IBE etching system process is employed to direct IBE etching beams at 0° deg and 180° deg with respect to the X-axis of the electrodes to thin the GST, and then the wafer (PCM cell can be rotated such that the IBE etching beams are directed at 90° deg and 270° deg (i.e., along a Y-axis) to remove the GST line width. This methodology advantageously avoids line-edge roughness patterning issues.

With respect to the IBE shadowing effect, this shadowing effect does not inherently require a pillar (which is circular), but does require a protruding feature (e.g., pillar, wall, etc). Since IBE could run parallel with the wafer surface, a particularly tall feature is not needed, though the taller features can open up the process window more. In an embodiment, a thickness range for the shadowing feature could be roughly 50 nm-500 nm which corresponds to the thickness of electrodes 12 in FIG. 4B, and could be adjusted based on aspect ratio to prevent defectivity concerns. In embodiments, a minimum 10% thickness reduction is needed in the target region compared to the full height in order to get a signal.

The methods described herein adds the thinning process step (i.e., IBE or CMP), but saves the cost of a mask, lithography/alignment, RIE/wet clean steps that would be needed to modulate bridge width by patterning.

The methods described herein form phase change memory (PCM) devices with a PCM bridge cell architecture having a thinned GST portion. In an embodiment, the PCM device includes two electrodes and the thickness of the PCM material, e.g., germanium-antimony-tellurium (GST), varies gradually from the electrodes towards the center of the bridge. The thinnest GST portion is at the center of the GST bridge.

Further, a phase change memory device having GST bridge including a thinned portion according to embodiments herein can be a multi-level PCM that is based on storing multiple resistance levels between a lowest (SET) and a highest (RESET) resistance value. Multiple resistance levels or levels correspond to partial-amorphous and partial-crystalline phase distributions of the PCM cell. Phase transformation, i.e., memory programming, may be enabled by Joule heating. In this regard, Joule heating may be controlled by a programming current or voltage pulse. Storing multiple resistance levels in a PCM cell typically resorts to iterative programming schemes, in particular with multiple write-verify steps until a desired resistance level is reached.

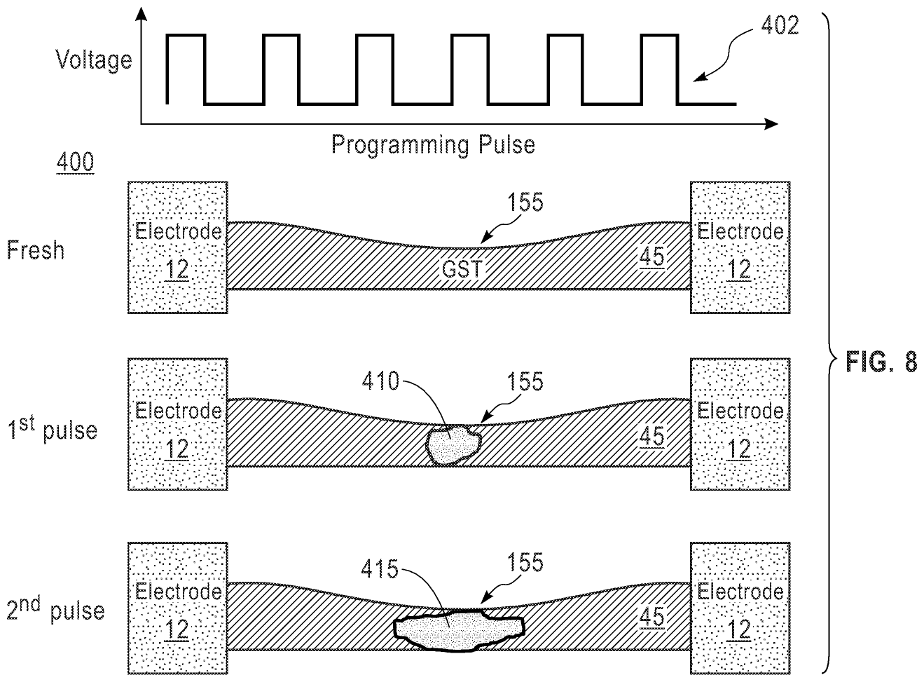

As shown in FIG. 8, phase change memory device 400 having GST bridge 45 including thinned portion 155 is programmed using a series of series of one or more pulses 402, corresponding to a weight update in machine learning, the phase change of GST occurs at the thinnest portion of the bridge and gradually propagates towards the electrodes. Such a gradual phase change allows gradual change of GST in both SET and RESET operations, which is highly desired for AI applications. That is, during SET/REST, the thinner center portion 155 has the highest current density and thus highest Joule heating. As a result, phase change starts at the center of the bridge and gradually propagates towards electrodes.

FIG. 8 particularly shows successive application of pulses 402 where a first applied pulse applied causes a first phase change 410 of GST material at the thinned portion 155 resulting in a first programmed resistance value (a partial-amorphous and partial-crystalline phase distribution). This can represent a first weight for use in a machine learning algorithm. A subsequent applied second pulse representing a further weight can be applied that causes a further phase change 415 of GST material at the thinned portion 155 resulting in a further programmed resistance value. Here the partially crystalline phase distribution has propagated towards the electrodes 12.

Thus, during PCM programming, corresponding to the weight update in machine learning, the phase change of GST occurs at the thinnest portion of the bridge and gradually propagates towards the electrodes. Such a gradual phase change allows gradual change of GST in both SET and RESET operations, which is highly desired for AI applications.

The methods and processes described herein thus result in the PCM memory device 400 having a thinned GST bridge portion is more efficient to induce switching of the PCM cell and further result in reduced operating current/voltage due to locally thinner PCM.

The methods and processes in embodiments herein do not rely on lithography/etch to define the minimum CD, so will not run into lithographic limits for small critical dimensions (CD). That is, there can be achieved in the PCM bridge memory cell low current/voltage requirements without small CD.

In general, any iterative pulse programming scheme aims to efficiently control the programming current through the cell in order to converge to the desired resistance level. For example, one solution proposed for multi-level PCM includes a programming scheme that applies write pulses with amplitudes that can be incrementally increased to approach the target resistance. In a second solution, a method is performed that starts in the SET state, i.e., in the fully crystalline mode, and applies melting pulses to gradually amorphize the PCM cell.

The phase change material device with GST bridge architecture embodying a weight for use in a machine learning operation in the embodiments herein can be a phase change memory cell among a plurality of phase change memory cells in a memory array.

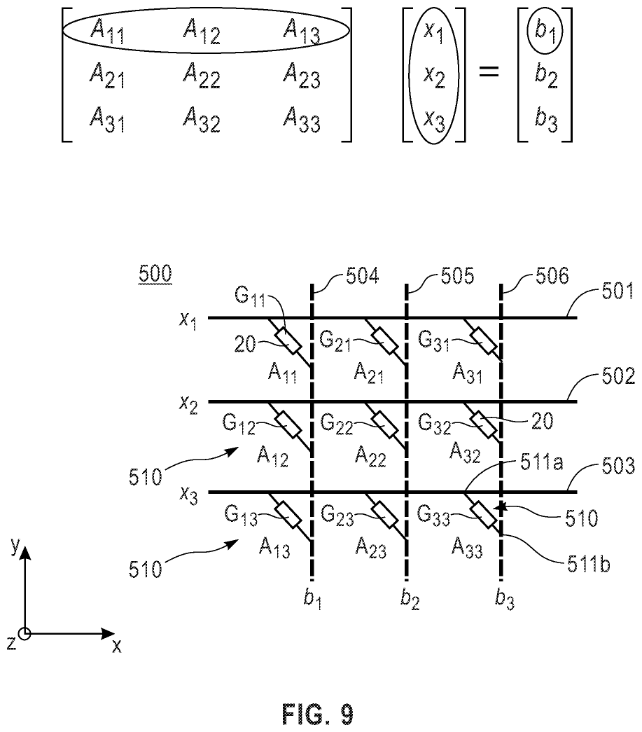

FIG. 9 illustrates an example of a resistive memory crossbar array 500 that can implement a matrix multiplication operation of a machine learning algorithm according to an embodiment of the invention. The matrix multiplication uses Ohm's law and Kirchhoff s law in the resistive memory crossbar array 500.

According to the illustrated example, a matrix A of size 3×3 can be multiplied with a vector x and the result is a product or result vector b:

$$[ \begin{matrix}{A}_{11} & {A}_{12} & {A}_{13} \\ {A}_{21} & {A}_{22} & {A}_{23} \\ {A}_{31} & {A}_{32} & {A}_{33}\end{matrix} ] [ \begin{matrix}{x}_{1} \\ {x}_{2} \\ {x}_{3}\end{matrix} ] = [ \begin{matrix}{b}_{1} \\ {b}_{2} \\ {b}_{3}\end{matrix} ]$$

Accordingly, the matrix A comprises a first column consisting of the matrix elements A₁₁, A₂₁ and A₃₁, a second column consisting of the matrix elements A₁₂, A₂₂ and A₃₂ and a third column consisting of the matrix elements A₁₃, A₂₃ and A₃₃. The vector x comprises the vector elements x₁, x₂ and x₃.

For such a multiplication of the matrix A with the size 3×3, a resistive memory comprises a memory crossbar array 500 of a corresponding size 3×3.

The memory crossbar array 500 comprises 3 row lines 501, 502 and 503 and three column lines 504, 505 and 506. The three row lines 501, 502 and 503 are arranged above the three column lines 504, 505 and 506 which is indicated by dotted lines.

The three row lines 501, 502 and 503 and the three column lines 504, 505 and 506 are connected to each other via junctions 510. The junctions 510 can extend in the vertical z-direction between upper cross points 511a of the row lines 501-503 and lower cross points 511b of the column lines 504-506.

Each junction 510 comprises a resistive element 20 such as the PCM bridge cell having gradually tapered surface profile as shown in FIG. 3B, 4D or 6D. For ease of illustration, the resistive element 20 corresponds to a single weights/conductance values Gᵢⱼ. The lower cross points 511b of junctions 510 correspond to an output node that is electrically connected to one of the respective column lines 504, 505 or 506 at the respective lower cross point 311b.

More particularly, the crossbar array 500 comprises 9 resistive memory elements 20, as illustrated according to embodiments depicted in FIG. 3B, 4D or 6D and represents a single weight Gᵢⱼ or in other words an individual conductance value Gᵢⱼ The column line 504 comprises single weights G₁₁, G₁₂ and G₁₃, the column line 505 comprises single weights G₂₁, G₂₂ and G₂₃ and the column line 506 single weights G₃₁, G₃₂ and G₃₃.

In order to perform the matrix vector multiplication of the above matrix, a signal generator (not shown) applies programming signals, in particular current pulses, to the resistive memory elements and thereby programs the conductance values for the matrix-vector multiplication.

More particularly, the conductance values of the resistive memory elements represent matrix values of the matrix of the matrix-vector multiplication. Accordingly, the conductance G₁₁ is programmed to the matrix value A₁₁, the conductance G₁₂ is programmed to the matrix value A₁₂, or more generally the conductance Gᵢⱼ is programmed to a corresponding matrix value Aij.

Then a readout circuit (not shown) can apply read voltages to the row lines 501, 502 and 503. More particularly, a readout circuit applies a read voltage X₁ to the row line 501, a read voltage X₂ to the row line 502 and a read voltage X₃ to the row line 503. Hence the read voltages represent vector values of the vector of the matrix-vector multiplication.

Furthermore, the readout circuit (not shown) can read out current values of the column lines 504, 505 and 506. As an example, the readout circuit (not shown) reads out a current value b₁ from the column line 504, which is the sum of three multiplications, namely b₁=A₁₁x₁+A₁₂x₂+A₁₃x₃.

Accordingly, the readout circuit can read out a current value b₂ from the column line 505 and a current value b₃ from the column line 506. The current values represent the result values of the vector elements of the product vector b.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A semiconductor structure comprising:
a substrate having formed thereon a first electrode and second electrodes physically spaced apart;
a phase change material cell directly on the substrate extending between the first and second electrodes, the phase change material including a first end electrically contacting the first electrode and a second end contacting the second electrode; and
the phase change material cell having a thinned surface portion wherein a surface topography of said phase change material cell at said thinned surface portion is decreased relative to a surface topography of said phase change material cell surface at each said first and second ends.

2. The semiconductor structure of claim 1, wherein the thinned surface portion includes a region having a decrease in height by ≥10% of an original surface height of the phase change material cell.

3. The semiconductor structure of claim 1, wherein the phase change material cell comprises a thinner width of said phase change material cell at the corresponding thinned surface portion relative to a width of said phase change material cell portion at each said first and second ends.

4. The semiconductor structure of claim 1, wherein the phase change material cell comprises a gradual topographic tapering of a surface height from said first electrode to said thinned surface region and a gradual tapering of a surface height from said second electrode to said thinned surface region.

5. The semiconductor structure of claim 1, wherein the phase change material cell includes a topographic angling of the surface of each said first electrode and second electrode.

6. The semiconductor structure of claim 1, wherein a width of the phase change material cell has a width that is thinner than a width of said first electrode and second electrode.

7. The semiconductor structure of claim 1, further comprising:
a first dummy electrode and second dummy electrode formed lengthwise on one side of said phase change material cell, a first gap separating said first dummy electrode and second dummy electrode; and
a third dummy electrode and fourth dummy electrode formed lengthwise on the opposite side of said phase change material cell, a second gap separating said first dummy electrode and second dummy electrode.

8. The semiconductor structure of claim 7, wherein the first gap and second gap are aligned with the thinned surface portion of said phase change material cell.

9. A method for forming a phase change memory element, the method comprising:
forming a first electrode and second electrode physically spaced apart on a substrate;
depositing a phase change material layer directly on the substrate between and said first electrode and second electrode, the phase change material including a first end electrically contacting the first electrode and a second end contacting the second electrode; and
forming a thinned surface portion of said phase change material layer between said first and second electrodes, wherein a surface topography of said phase change material cell at said thinned surface portion is decreased relative to a surface topography of said phase change material cell surface at each said first and second ends.

10. The method of claim 9, wherein said forming a thinned surface portion of said phase change material layer between said first and second electrodes comprises: forming a region having a decrease in height by ≥10% of an original surface height of the phase change material cell.

11. The method of claim 9, wherein said forming a thinned surface portion of said phase change material layer between said first and second electrodes comprises: forming a thinner width of said phase change material layer at the corresponding thinned surface portion relative to a width of said phase change material cell portion at each said first and second ends.

12. The method of claim 9, wherein said forming a thinned surface portion of said phase change material layer between said first and second electrodes comprises: forming a gradual topographic tapering of a surface height from said first electrode to said thinned surface region and a gradual tapering of a surface height from said second electrode to said thinned surface region.

13. The method of claim 9, wherein said forming a thinned surface portion of said phase change material layer between said first and second electrodes comprises:
performing a chemical-mechanical polishing (CMP) process to achieve said decreased surface topography of said phase change material layer at said thinned surface portion.

14. The method of claim 9, wherein said forming a thinned surface portion of said phase change material layer between said first and second electrodes comprises:
performing an ion-beam etching (IBE) process directing particle beams at a low tilt angle relative to a horizontal to achieve said decreased surface topography of said phase change material layer at said thinned surface portion.

15. The method of claim 14, wherein said performing an ion-beam etching (IBE) process further achieves a topographic angling of the surface of each said first electrode and second electrode.

16. The method of claim 9, further comprising:
forming a first dummy electrode and second dummy electrode lengthwise on one side of said phase change material layer, a first gap separating said first dummy electrode and second dummy electrode; and
forming a third dummy electrode and fourth dummy electrode formed lengthwise on the opposite side of said phase change material layer, a second gap separating said first dummy electrode and second dummy electrode, the first gap and second gap being aligned with the thinned surface portion of said phase change material layer.

17. The method of claim 16, wherein said forming a thinned surface portion of said phase change material layer between said first and second electrodes comprises:
performing an ion-beam etching (IBE) process directing respective first and second particle beams at a low tilt angle relative to a horizontal between respective said first gap and said second gap to additionally achieve a decreased width of said phase change material layer at said thinned surface portion.

18. A method of programming a phase change material (PCM) memory device comprising:
initializing a resistive state of a PCM memory device, the PCM memory device comprising:
a substrate having formed thereon a first electrode and second electrodes physically spaced apart;
a phase change material cell directly on the substrate extending between the first and second electrodes, the phase change material including a first end electrically contacting the first electrode and a second end contacting the second electrode; and
the phase change material cell having a thinned surface portion wherein a surface topography of said phase change material cell at said thinned surface portion is decreased relative to a surface topography of said phase change material cell surface at each said first and second ends; and
applying an electronic pulse signal to said first or second electrode to cause a resistive state change of said phase change material cell at a location corresponding to said thinned surface portion.

19. The method of claim 18, further comprising:
applying a further electronic pulse signal to said first or second electrode to cause a further resistive state change of said phase change material cell propagating from the location corresponding to said thinned surface portion towards said first and second electrodes.

20. The method of claim 18, wherein an applied electronic pulse signal corresponds to a weight update in a machine learning algorithm.
